(19) United States
(12) Patent Application Publication
(10) Pub. No.: US 2014/0285214 A1
(43) Pub. Date: Sep. 25, 2014

(54) ELECTRICAL INSULATING PROPERTY TESTER, ELECTRICAL INSULATING PROPERTY TESTING METHOD AND ELECTRICALLY INSULATED WIRE PRODUCING METHOD

(71) Applicant: Hitachi Metals, Ltd., Tokyo (JP)

(72) Inventors: XIE Peng, Hitachi (JP); Hideyuki Kikuchi, Hitachi (JP); Daisuke Hino, Hamamatsu (JP)

(73) Assignee: Hitachi Metals, Ltd., Tokyo (JP)

(21) Appl. No.: 14/191,200

(22) Filed: Feb. 26, 2014

(30) Foreign Application Priority Data
Mar. 21, 2013 (JP) 2013-057684

(51) Int. Cl. G01R 31/12

(52) U.S. Cl. CPC G01R 31/1272
USPC 324/551

(57) ABSTRACT

An electrical insulating property tester includes a guaranteed voltage applying unit for applying a guaranteed voltage to a running line provided with an electrical insulating layer around an electrical conducting wire, a grounding unit arranged downstream of the guaranteed voltage applying unit, for grounding the running line to thereby remove electric charge electrostatically induced on the running line, and a test voltage applying unit arranged downstream of the grounding unit, for applying a test voltage lower than the guaranteed voltage to the running line, to thereby detect a leakage current value.

The present application is based on Japanese patent application No.2013-057684 filed on Mar. 21, 2013, the entire contents of which are incorporated herein by reference.

### BACKGROUND OF THE INVENTION

1. Field of the Invention

This invention relates to an electrical insulating property tester, an electrical insulating property testing method and an electrically insulated wire producing method.

2. Description of the Related Art

Generally, an electrically insulated wire is provided with an electrical conducting wire (core wire), and an electrical insulating layer, which is formed by coating an electrical insulating material around the electrical conducting wire. Such an electrically insulated wire is produced by an electrically insulated wire producing equipment comprising an electrical insulating material coater for applying the electrical insulating material around the electrical conducting wire, and a take-up roll for winding the electrically insulated wire thereon, such as a bobbin or the like.

An electrical insulating property of the electrically insulated wire is evaluated by, for example a breakdown voltage (BDV) measuring test. That is, the electrical insulating property of the electrically insulated wire is evaluated by applying a predetermined voltage (test voltage) to the electrically insulated wire, and measuring a leakage current value. In this evaluation method, the breakdown voltage is a voltage at which the leakage current value exceeds a predetermined threshold, and the electrical insulating property is evaluated from a change in the leakage current value.

The evaluation of the electrical insulating property of the electrically insulated wire is done by taking samples at least one by one having a predetermined length from both ends of the electrically insulated wire, i.e. a winding starting portion and a winding ending portion, respectively, of the electrically insulated wire wound by the take-up roll. That is, the breakdown voltages are detected from changes in the leakage current values, respectively, of each sample taken from the electrically insulated wire, and if the breakdown voltages of all the samples are not lower than a predetermined value (i.e., a voltage to guarantee the given electrical insulating property of the electrically insulated wire), the electrically insulated wire is evaluated as having the desired electrical insulating property over its entire length. In this evaluation method, however, due to only the electrical insulating properties at both the ends, respectively, of the electrically insulated wire being evaluated, evaluated results for the electrical insulating property over the entire length of the electrically insulated wire have been likely to vary significantly according to the sampling method, the number of samplings, etc. In other words, the electrical insulating property over the entire length of the electrically insulated wire has been likely to be unable to be securely guaranteed.

Accordingly, JP-A-2001-349923 has suggested that the evaluation test for the electrical insulating property over the entire length of the electrically insulated wire is performed by running the electrical conducting wire, forming the electrical insulating layer around the electrical conducting wire to form the electrically insulated wire, performing the electrical insulating property evaluation test, and thereafter winding the electrically insulated wire on the take-up roll. That is, it has been suggested that the electrical insulating property evaluation test for the electrically insulated wire is performed in an in-line producing process for the electrically insulated wire. Specifically, as shown in, for example FIG. 2, with an electrical insulating layer forming device 3′, an electrical insulating varnish is applied around the electrical conducting wire to form an electrical insulating layer therearound, resulting in the electrically insulated wire, and with a test voltage applying unit 10′, such as a spark tester, which is provided between the electrical insulating layer forming device 3′ and the take-up roll 4′, as a detector to apply the predetermined test voltage to the electrically insulated wire which is a running line 5′ to detect the leakage current value, the test voltage is applied to the electrically insulated wire, thereby measuring the leakage current value. Then, a change in the leakage current value is detected by the test voltage applying unit 10′, and if the leakage current value exceeds a predetermined threshold, the electrically insulated wire is detected as a defective product breaking down.

Refer to JP-A-2001-349923, for example.

### SUMMARY OF THE INVENTION

In the in-line electrical insulating property evaluation test, however, in order to ensure the electrical safety of the production line, the test voltage to be applied to the electrically insulated wire is often set at the order of a few hundred volts. In contrast, the breakdown voltage of a general electrically insulated wire (enameled wire) is often a few kilovolts. Therefore, when the test voltage has been a few hundred volts, unless the electrical insulating property of the electrical insulating layer has been very poor, it has been likely to be difficult to evaluate the electrical insulating property from the change in leakage current value. That is, when the test voltage has been low, due to the leakage current value having been small even in the event of electrical insulating layer breakdown, the change in leakage current value has been unlikely to be detected. Therefore, even if the electrically insulated wire has broken down, it has not been able to be detected as a defective product, but has been likely to be produced as having an inadequately guaranteed electrical insulating property.

Accordingly, it is an object of the present invention to provide a tester, a testing method and an electrically insulated wire producing method, capable of obviating the foregoing drawbacks, and more precisely testing an electrical insulating property over an entire length of an electrically insulated wire.

In order to obviate the above drawbacks, the present invention is configured as follows.

(1) According to a first feature of the invention, an electrical insulating property tester comprises:

a guaranteed voltage applying unit for applying a guaranteed voltage to a running line comprising an electrical insulating layer around an electrical conducting wire;

a grounding unit arranged downstream of the guaranteed voltage applying unit, for grounding the running line to thereby remove electric charge electrostatically induced on the running line; and

a test voltage applying unit arranged downstream of the grounding unit, for applying a test voltage lower than the guaranteed voltage to the running line, to thereby detect a leakage current value.

(2) According to a second feature of the invention, an electrical insulating property testing method comprises:

with a guaranteed voltage applying unit, applying a guaranteed voltage to a running line comprising an electrical insulating layer around an electrical conducting wire;

with a grounding unit arranged downstream of the guaranteed voltage applying unit, grounding the running line to thereby remove electric charge electrostatically induced on the running line; and

with a test voltage applying unit arranged downstream of the grounding unit, applying a test voltage to the running line, to thereby detect a leakage current value.

(3) According to a third feature of the invention, an electrically insulated wire producing method comprises:

applying an electrical insulating material around an electrical conducting wire to form an electrical insulating layer around the electrical conducting wire to form an electrically insulated wire;

with a guaranteed voltage applying unit, applying a guaranteed voltage to the electrically insulated wire;

with a grounding unit arranged downstream of the guaranteed voltage applying unit, grounding the electrically insulated wire to thereby remove electric charge remaining on the electrical insulating layer; and

with a test voltage applying unit arranged downstream of the grounding unit, applying a test voltage to the electrically insulated wire, to thereby detect a leakage current value.

(Points of the Invention)

The tester, the testing method and the electrically insulated wire producing method according to the present invention allow for more precisely testing the electrical insulating property over an entire length of the electrically insulated wire.

### BRIEF DESCRIPTION OF THE DRAWINGS

The preferred embodiments according to the invention will be explained below referring to the drawings, wherein:

FIG. 1 is a schematic configuration diagram showing an electrically insulated wire producing equipment including a tester in one embodiment according to the invention; and

FIG. 2 is a schematic configuration diagram showing an electrically insulated wire producing equipment including a conventional tester.

### DETAILED DESCRIPTION OF THE PREFERRED EMBODIMENTS

First, prior to the description of an embodiment of the present invention, the Inventors' findings will be explained. As described above, in the in-line electrical insulating property evaluation test, the test voltage to be applied to the electrically insulated wire which is the running line is often set to be as low as the order of a few hundred volts. Therefore, even if the electrically insulated wire breaks down, it cannot be detected as a defective product, but is likely to be produced as having an inadequately guaranteed electrical insulating property. Accordingly, in order to enhance the guarantee of the electrical insulating property over an entire length of the electrically insulated wire, the Inventors have focused on applying a high test voltage of the same order (a few kilovolts, for example) as a voltage (guaranteed voltage) required to guarantee the electrical insulating property of the electrically insulated wire. The present invention is based on the Inventors' findings above.

(1) Configuration of Electrically Insulated Wire Producing Equipment and Electrical Insulating Property Tester

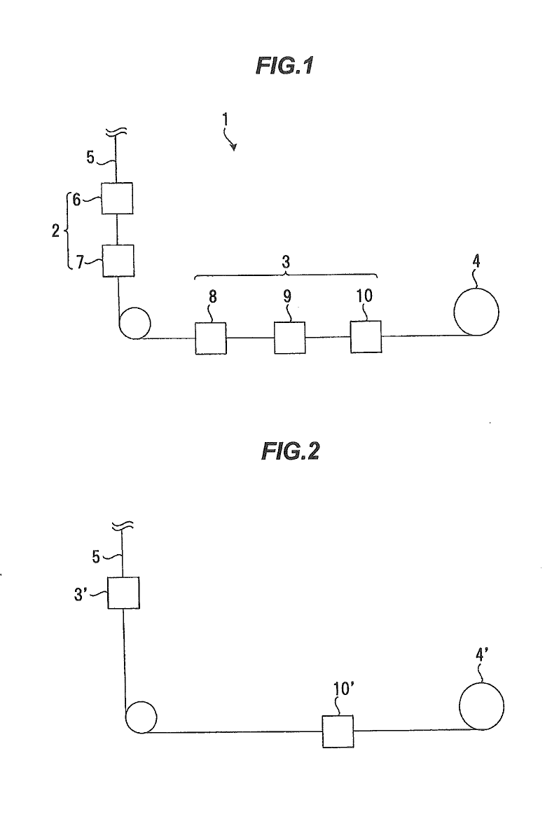

First, the configuration of the of an electrically insulated wire producing equipment and an electrical insulating property tester in one embodiment of the present invention will be described mainly with reference to FIG. 1. FIG. 1 is a schematic configuration diagram showing the electrically insulated wire producing equipment including the electrical insulating property tester in the present embodiment.

As shown in FIG. 1, an electrically insulated wire producing equipment 1 in the present embodiment is configured as including, in turn from upstream, an electrical insulating layer forming device 2 for applying an electrical insulating material around an electrical conducting wire (core wire) and curing the electrical insulating material to form an electrical insulating layer, a tester 3, and a take-up roll 4.

The electrical insulating layer forming device 2 is configured as including an electrical insulating material coater 6 for applying the electrical insulating material around the electrical conducting wire which is a running line 5, and a curing furnace 7 for curing the electrical insulating material to form the electrical insulating layer around the electrical conducting wire. The electrical conducting wire may comprise, e.g. a wire including copper, aluminum or the like. The electrical insulating material may comprise, e.g. an electrical insulating varnish comprising a resin such as a polyamide imide resin, a polyimide resin, a polyester imide resin or the like dissolved in a solvent. The curing furnace 7 may comprise, e.g. a heating furnace or the like.

Downstream of the electrical insulating layer forming device 2 is arranged the tester 3 which tests electrical insulating property (withstanding voltage property) of the electrically insulated wire which is the running line 5. The tester 3 is provided with a guaranteed voltage applying unit 8 for applying a guaranteed voltage to the electrically insulated wire. The guaranteed voltage is a voltage that is required to guarantee the electrical insulating property of the electrically insulated wire. That is, the guaranteed voltage is indicative of the maximum withstand voltage capability of the electrically insulated wire. Thus, typically, as the guaranteed voltage, a high voltage of a few kilovolts which is a few times higher than a test voltage to be described later is applied to the electrically insulated wire. The guaranteed voltage applying unit 8 includes at least one electrode (electrode plate), which applies a guaranteed voltage to the electrically insulated wire, and a power supply, which is connected to that electrode to apply the guaranteed voltage to that electrode. That is, the guaranteed voltage applying unit 8 is configured so as to apply a guaranteed voltage from the power supply to the electrode, and apply the guaranteed voltage applied to the electrode to the running line 5.

Downstream of the guaranteed voltage applying unit 8 is arranged a grounding unit 9 comprising at least one grounded electrode as a grounding member. The grounding unit 9 is configured so as to bring the ground electrode into contact with the electrically insulated wire which is the running line 5, to thereby cause the guaranteed voltage applying unit 8 to apply the guaranteed voltage to the electrically insulated wire, to thereby remove electric charge electrostatically induced on the surface of the electrically insulated wire.

Downstream of the grounding unit 9 is arranged a test voltage applying unit 10 to evaluate the electrical insulating property of the electrically insulated wire. The test voltage applying unit 10 is configured so as to apply a test voltage to the electrically insulated wire, to detect a leakage current value. The test voltage applied by the test voltage applying unit 10 is set at a voltage (a voltage of the order of a few hundred volts, for example) lower than the guaranteed voltage. The test voltage applying unit 10 may comprise, e.g. a spark tester, a device which brings the electrically insulated wire which is the running line 5 into contact with at least one pulley respectively, to measure an electric current value produced in the contacted area as the leakage current value, a carbon brush, or the like.

The tester 3 in the present embodiment mainly comprises the guaranteed voltage applying unit 8, the grounding unit 9, and the test voltage applying unit 10.

As described above, the tester 3 applies the electrical insulating property testing voltage in two parts to the electrically insulated wire which is the running line 5. That is, the guaranteed voltage is applied to the electrically insulated wire by the guaranteed voltage applying unit 8, and thereafter the test voltage lower than the guaranteed voltage is applied to the electrically insulated wire by the test voltage applying unit 10. Thus, it is possible to ensure safety, suppress the occurrence of spark discharge, and more precisely test the electrical insulating property over an entire length of the electrically insulated wire.

That is, after the guaranteed voltage applying unit 8 applying the high guaranteed voltage to the electrically insulated wire, the grounding unit 9 grounds the electrically insulated wire, thereby removing the electric charge electrostatically induced on the electrically insulated wire. Thus, it is possible to prevent the electrically insulated wire with the electric charge remaining on the electrically insulated wire from being wound on a take-up roll 4 which will be described later. Therefore, it is possible to ensure safety. For example, when a user replaces the take-up roll 4 to be described later with the electrically insulated wire wound thereon, and even when the user is in contact with the electrically insulated wire, it is possible to prevent the electric shock of the user, and thereby enhance the safety of the user.

Further, after the electrically insulated wire being grounded by the grounding unit 9, the test voltage which is as low as a few hundred volts is applied to the electrically insulated wire by the test voltage applying unit 10. Thus, when the electrically insulated wire which is the running line 5 runs in the test voltage applying unit 10, even if the electrically insulated wire that vibrates due to running and the test voltage applying unit 10 contact together, it is possible to prevent the occurrence of spark discharge at the contacted area between the running line 5 and the test voltage applying unit 10. Therefore, it is possible to suppress a fault in the tester 3 (the test voltage applying unit 10, for example), and precisely detect the leakage current value for the electrically insulated wire. As a result, it is possible to more precisely test the electrical insulating property over the entire length of the electrically insulated wire, and more securely guarantee the electrical insulating property.

Downstream of the tester 3, that is, at an end of the electrically insulated wire producing equipment 1 is arranged a take-up roll 4. The take-up roll 4 is configured so as to wind the electrically insulated wire thereon which is the running line 5 at a predetermined speed. The take-up roll 4 is configured so as to adjust the winding speed (rotary speed), and thereby adjust the running speed of the running line 5. The take-up roll 4 may comprise, e.g. a bobbin or the like.

(2) Electrically Insulated Wire Producing Method and Electrical Insulating Property Testing Method

The following describes an electrically insulated wire producing method and an electrical insulating property testing method in one embodiment of the present invention. The electrically insulated wire producing method and the electrical insulating property testing method are implemented by the electrically insulated wire producing equipment 1 and the tester 3 described above.

(Electrical Insulating Layer Forming Step)

First, with the electrical insulating layer forming device 2, an electrically insulated wire is formed. That is, with the electrical insulating material coater 6 provided in the electrical insulating layer forming device 2, an electrical insulating material is applied around an electrical conducting wire which is a wire including, for example copper, aluminum or the like. Then, the electrical conducting wire coated with the electrical insulating material therearound is passed to a curing furnace 7 provided in the electrical insulating layer forming device 2, and the electrical insulating material is cured to form an electrical insulating layer around the electrical conducting wire, resulting in the electrically insulated wire being formed.

(Electrical Insulating Property Testing Step)

Subsequently, the electrically insulated wire which is the running line 5 is introduced to the tester 3 and the electrical insulating property of the electrically insulated wire is tested. That is, the electrical insulating property testing voltage is applied in two parts to the electrically insulated wire, and testing is done as to whether breakdown is not occurring in the electrically insulated wire. Thus, it is possible to ensure safety, suppress the occurrence of spark discharge, and more precisely test the electrical insulating property over the entire length of the electrically insulated wire. Further, by testing the electrical insulating property after the aforementioned electrical insulating layer forming step and before a later described winding step, that is, by testing the in-line electrical insulating property, it is possible to more precisely test the electrical insulating property over the entire length of the electrically insulated wire. Thus, it is possible to more securely guarantee the electrical insulating property over the entire length of the electrically insulated wire.

<Guaranteed Voltage Applying Step>

First, the electrically insulated wire is introduced and run within the guaranteed voltage applying unit 8 comprising the at least one electrode (electrode plate), which applies the guaranteed voltage to the electrically insulated wire which is the running line 5, and the power supply, which is connected to that electrode to apply the guaranteed voltage to that electrode. At this point, the guaranteed voltage is continuously applied by the guaranteed voltage applying unit 8 to the electrically insulated wire running within the guaranteed voltage applying unit 8. That is, the guaranteed voltage is applied to the at least one electrode (electrode plate) by the power supply provided in the guaranteed voltage applying unit 8, so that the guaranteed voltage is applied from the electrode to the electrically insulated wire.

<Grounding Step>

After the guaranteed voltage application step is completed, the electrically insulated wire which is the running line 5 is introduced and run in the grounding unit 9. At this point, the at least one ground electrode provided in the grounding unit 9 is brought into contact with the electrically insulated wire, and the electrically insulated wire which is the running line 5 is continuously grounded. Then, the guaranteed voltage is applied by the guaranteed voltage applying unit 8 to the electrically insulated wire, thereby removing the electric charge electrostatically induced on the electrically insulated wire (the surface of the electrical insulating layer). Thus, it is possible to ensure safety. For example, when a user replaces the take-up roll 4 to be described later with the electrically insulated wire wound thereon, and even when the user is in contact with the electrically insulated wire, it is possible to prevent the electric shock of the user, and thereby enhance the safety of the user.

<Test Voltage Applying Step>

After the grounding step is completed, the electrically insulated wire which is the running line 5 is introduced and run in the test voltage applying unit 10. At this point, the test voltage (of the order of a few hundred volts, for example) lower than the guaranteed voltage is continuously applied by the test voltage applying unit 10 to the electrically insulated wire running within the test voltage applying unit 10. Thus, when the electrically insulated wire which is the running line 5 runs in the test voltage applying unit 10, it is possible to reduce the occurrence of spark discharge at the contacted area between the running line 5 and the test voltage applying unit 10, Therefore, it is possible to suppress a fault in the tester 3 (a leakage current value measurement device 12, for example), and precisely detect a leakage current value for the electrically insulated wire. As a result, it is possible to more precisely test the electrical insulating property over the entire length of the electrically insulated wire, and more securely guarantee the electrical insulating property.

<Electrical Insulating Property Evaluating Step>

After the test voltage is applied by the test voltage applying unit 10 to the electrically insulated wire which is the running line 5, the leakage current value for the electrically insulated wire is continuously detected, and testing is done as to whether the leakage current value is not exceeding a predetermined threshold. At this point, if the electrically insulated wire breaks down at the guaranteed voltage, since the electrical insulating property is lost, even in the case of applying the low test voltage of the order of a few hundred volts, the leakage current value is high. That is, if the leakage current value is not greater than the given threshold value, the electrically insulated wire does not break down, and it is possible to evaluate that the required electrical insulating property is being maintained. On the other hand, if the leakage current value is greater than the given threshold value, the electrically insulated wire breaks down at the guaranteed voltage, and it is possible to evaluate that the electrical insulating property is being lost.

Here, a case that the required guaranteed voltage for the electrically insulated wire with a thickness of the electrical insulating layer of 30 μm is 3 kV will be described as one example. First, the guaranteed voltage of 3 kV is applied by the guaranteed voltage applying unit 8 to the electrically insulated wire voltage. Then, after the electrically insulated wire voltage is grounded by the grounding unit 9, the test voltage of 300 V is applied by the test voltage applying unit 10 to the electrically insulated wire, and the leakage current value is continuously measured by the test voltage applying unit 10. At this point, if no breakdown occurs in the electrically insulated wire, the leakage current value is 10 μA or less. Therefore, if the leakage current value detected by the test voltage applying unit 10 is more than 10 μA, the electrically insulated wire breaks down, and it is possible to evaluate that the electrical insulating performance of the electrically insulated wire is being lost.

(Winding Step)

The electrically insulated wire passed through the tester 3 and with the guaranteed electrical insulating property is wound sequentially by the take-up roll 4. In this manner, the producing process for the electrically insulated wire in the present embodiment is completed.

### (3) ADVANTAGEOUS EFFECTS OF THE PRESENT EMBODIMENT

In the present embodiment, the tester 3 for testing the electrical insulating property includes, in turn from upstream, the guaranteed voltage applying unit 8, the grounding unit 9, and the test voltage applying unit 10. Then, after applying the high guaranteed voltage of a few kV to the electrically insulated wire, and grounding the electrically insulated wire, the low test voltage of a few hundreds of V is applied to the electrically insulated wire, thereby detecting the leakage current value. That is, the tester 3 is configured so as to apply the electrical insulating property testing voltage in two parts (i.e. for two separate times) to the electrically insulated wire which is the running line 5, to test whether breakdown is not occurring in the electrically insulated wire. Accordingly, it is possible to ensure safety, suppress the occurrence of spark discharge, and more precisely test the electrical insulating property over the entire length of the electrically insulated wire.

### ANOTHER EMBODIMENT OF THE PRESENT INVENTION

Although the specific embodiment of the present invention has been described above, the invention is not limited to the above embodiment, but various alterations may be made without departing from the spirit and scope of the invention.

For example, between the tester 3 and the take-up roll 4, there may be provided a grounding unit with the test voltage applying unit 10 applying the test voltage to thereby remove electric charge electrostatically induced on the surface of the electrically insulated wire. Thus, it is possible to further enhance safety.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An electrical insulating property tester, comprising:
a guaranteed voltage applying unit for applying a guaranteed voltage to a running line comprising an electrical insulating layer around an electrical conducting wire;
a grounding unit arranged downstream of the guaranteed voltage applying unit, for grounding the running line to thereby remove electric charge electrostatically induced on the running line; and
a test voltage applying unit arranged downstream of the grounding unit, for applying a test voltage lower than the guaranteed voltage to the running line, to thereby detect a leakage current value.

2. An electrical insulating property testing method, comprising:
with a guaranteed voltage applying unit, applying a guaranteed voltage to a running line comprising an electrical insulating layer around an electrical conducting wire;
with a grounding unit arranged downstream of the guaranteed voltage applying unit, grounding the running line to thereby remove electric charge electrostatically induced on the running line; and
with a test voltage applying unit arranged downstream of the grounding unit, applying a test voltage to the running line, to thereby detect a leakage current value.

3. An electrically insulated wire producing method, comprising:
applying an electrical insulating material around an electrical conducting wire to form an electrical insulating layer around the electrical conducting wire to form an electrically insulated wire;
with a guaranteed voltage applying unit, applying a guaranteed voltage to the electrically insulated wire;
with a grounding unit arranged downstream of the guaranteed voltage applying unit, grounding the electrically insulated wire to thereby remove electric charge remaining on the electrical insulating layer; and
with a test voltage applying unit arranged downstream of the grounding unit, applying a test voltage to the electrically insulated wire, to thereby detect a leakage current value.
